(19) United States
(12) Patent Application Publication
(10) Pub. No.: US 2012/0064260 A1
(43) Pub. Date: Mar. 15, 2012

(54) SURFACE WAVE PLASMA CVD APPARATUS AND FILM FORMING METHOD

(75) Inventor: Masayasu Suzuki, Atsugi-shi (JP)

(73) Assignee: SHIMADZU CORPORATION, Kyoto-shi, Kyoto (JP)

(21) Appl. No.: 13/319,468

(22) PCT Filed: May 15, 2009
(86) PCT No.: PCT/JP2009/059084

§ 371 Date: Nov. 8, 2011

(51) Int. Cl. C23C 16/511; C23C 16/455; C23C 16/52

(52) U.S. Cl. 427/575; 118/706

(57) ABSTRACT

A surface wave plasma CVD apparatus includes a waveguide connected to a microwave source with slot antennae; a dielectric member that introduces microwaves from slot antennae into a plasma processing chamber to generate surface wave plasma; a moving device that reciprocatory moves a subject of film formation such that the subject passes a film formation processing region facing the dielectric member; a control device that controls the reciprocatory movement of the subject of film formation by the moving device depending on film forming conditions to perform film formation on the subject; and gas ejection parts provided in parallel in a direction at right angles to a direction along which the subject is moved at predetermined positions between the subject that passes through the film formation processing region and the dielectric member. Each of the gas ejection parts has a slit extending parallel to the dielectric member.

### TECHNICAL FIELD

The present invention relates to a surface wave plasma CVD apparatus and a film forming method using the same.

### BACKGROUND ART

Heretofore, a CVD apparatus that utilizes surface wave plasma has been known (cf., for example, Patent Reference 1). In the surface wave plasma CVD apparatus, micro wave is introduced into a vacuum chamber through a dielectric window provided thereat. The micro wave propagates as a surface wave along an interface between the plasma and the dielectric window. As a result, high density plasma is generated in the vicinity of the dielectric window. A substrate on which a film is to be formed is stationary arranged at a position facing the dielectric window.

### CITATION LIST

### Patent Literature

Patent Literature 1: Japanese Patent Application Laid-open Publication No. 2005-142448

### SUMMARY OF INVENTION

### Technical Problem

However, the generated plasma has a distribution of density that is not always uniform within a region corresponding to the dielectric window. For example, the density of the generated plasma decreases in peripheral regions around the dielectric window. As such the area of the dielectric window must be set to be larger than the area of the substrate, which is a subject on which a film is to be formed, resulting in a difficulty to control the system to obtain uniform high density plasma for covering a large surface area as large as 2.5 m×2.5 m as liquid crystal glass substrates and an increase in production cost. In the case of high density plasma such as surface wave plasma, it is important to provide material process gas uniformly onto the plasma region in order to make the quality of film or thickness of film uniform. For this purpose, it is necessary to arrange gas ejection parts finely. When the substrate has a large surface area, it is sometimes the case that the gas feed pipes are arranged in the plasma, which causes a problem that particles tend to be generated thereon.

In the case of high density plasma such as surface wave plasma, it is important to provide material process gas uniformly at a suitable position in order to make uniform the quality of film or thickness of film. However, a method of ejecting gas through holes or the like provided in the gas feed pipe has been generally used by the conventional apparatus resulting in quite a lot of gas coming off from the suitable plasma region.

### Solution to Problem

The surface wave plasma CVD apparatus according to the present invention comprises: a waveguide that is formed of a plurality of slot antennae and connected to a microwave source; a dielectric member that introduces microwaves emitted from the plurality of slot antennae into a plasma processing chamber to generate surface wave plasma; a moving device that reciprocates a subject of film formation in the form of a substrate such that the subject of film formation passes a film formation processing region facing the dielectric member; a control device that controls reciprocation of the subject of film formation by the moving device depending on film formation conditions to perform film formation on the subject of film formation; and a plurality of gas ejection parts provided in parallel in a direction at right angles to a direction along which the subject of film formation is moved at predetermined positions between the subject of film formation that passes through the film formation processing region and the dielectric member, wherein each of the plurality of gas ejection parts is provided with a slit extending parallel to the dielectric member, allowing the material process gas to be ejected through the slit in the direction along which the subject of film formation is moved.

The plasma processing chamber may be provided with a first standby region and a second standby region where the subject of film formation does not oppose the dielectric member such that the film formation processing region that opposes the dielectric member is sandwiched by the first and second standby regions along a course of movement of the subject of film formation, and the moving device may reciprocate the subject of film formation between the first and second standby regions.

A gas baffle member that is arranged facing the direction of ejection of the gas ejection part and convects the ejected material process gas in a region where the surface wave plasma is generated may be provided.

A back plate that controls temperature of the subject of film formation may be arranged over an entire region over which the subject of film formation is moved by the moving device.

A back plate driving device that varies a distance between the subject of film formation and the back plate may be provided.

The apparatus may be configured such that the subject of film formation comprises a film-like substrate, the back plate supports the film-like substrate in a region facing the dielectric member, and the moving device reciprocates the film-like substrate so that a region of the film-like substrate in which a film is to be formed passes through the film formation processing region.

The subject of film formation may comprise a functional device on a substrate, and a protective film that protects the functional device is formed.

The film forming method according to the present invention is a method of forming a film on a subject of film formation by using a surface wave plasma CVD apparatus according to any one of claims 1 to 7, the method comprising: forming film layers under different film forming conditions between a forward route and a backward route of the reciprocatory motion, thereby forming a thin film having laminated the film layers formed under the different film forming conditions.

### Advantageous Effect of the Invention

According to the present invention, film formation is performed while a target on which a film is to be formed is in reciprocating motion such that the target on which a film is to be formed will pass a region facing the dielectric member. This allows a thin film having uniform quality and thickness of film to be formed at low cost.

### BRIEF DESCRIPTION OF THE DRAWINGS

FIG. 1 presents a diagram illustrating a first embodiment of the present invention, showing a schematic configuration of a surface wave plasma CVD apparatus;

FIG. 2 presents a cross-sectional view along a line A-A in FIG. 1;

FIG. 3 presents a cross-sectional view along a line B-B in FIG. 1;

FIG. 4 presents a diagram illustrating a second embodiment, showing a schematic configuration of a surface wave plasma CVD apparatus;

FIG. 5 presents a cross-sectional view along a line B-B in FIG. 4;

FIG. 6 presents a diagram illustrating the function of the gas baffle plate 1b;

FIG. 7 presents a diagram illustrating the second embodiment, with (a) being an enlarged diagram of the gas ejection part 52, (b) being a diagram of the gas ejection part 52 as seen from the direction of ejection, and (c) being a cross-section along the line C-C;

FIG. 8 presents schematic illustration about differences in the manner of diffusion of the ejected gas between the cases with and without the slit 521, with (a) being a side view, (b) being a top view, and (c) being a view as seen from the direction D;

FIG. 9 presents a diagram showing another example of the gas ejection part 52;

FIG. 10 presents schematic diagrams illustrating the distribution of material process gas in the vacuum chamber 1, with (a) being a plan view and (b) being a front view;

FIG. 11 presents a diagram illustrating a fourth embodiment;

FIG. 12 presents a diagram showing the apparatus shown in FIG. 11, in which the gas baffle plate 11 is provided;

FIG. 13 shows an example of a conventional surface wave plasma CVD apparatus that does not perform reciprocatory motion of the substrate, with (a) being a plan view and (b) being a front view;

FIG. 14 presents a diagram illustrating a relationship between the flux ratio of nitrogen in the process gas and the internal stress of a silicon nitride film;

FIG. 15 presents a diagram showing a cross-sectional surface of the laminate thin film 100 formed by alternately laminating a silicon nitride layer with a compression stress and a silicon nitride film with a tensile stress; and

FIG. 16 presents a cross-sectional view showing an organic EL element formed on a plastic film substrate.

### DESCRIPTION OF EMBODIMENTS

Hereafter, best modes for carrying out the present invention are explained with reference to the attached drawings.

### First Embodiment

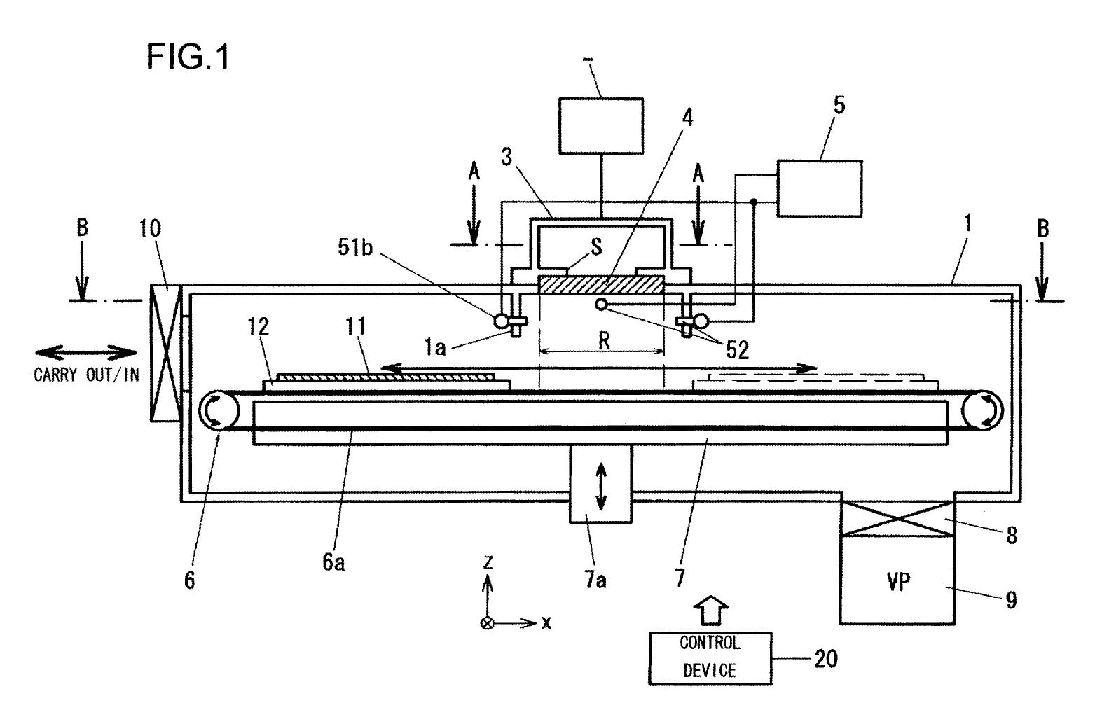

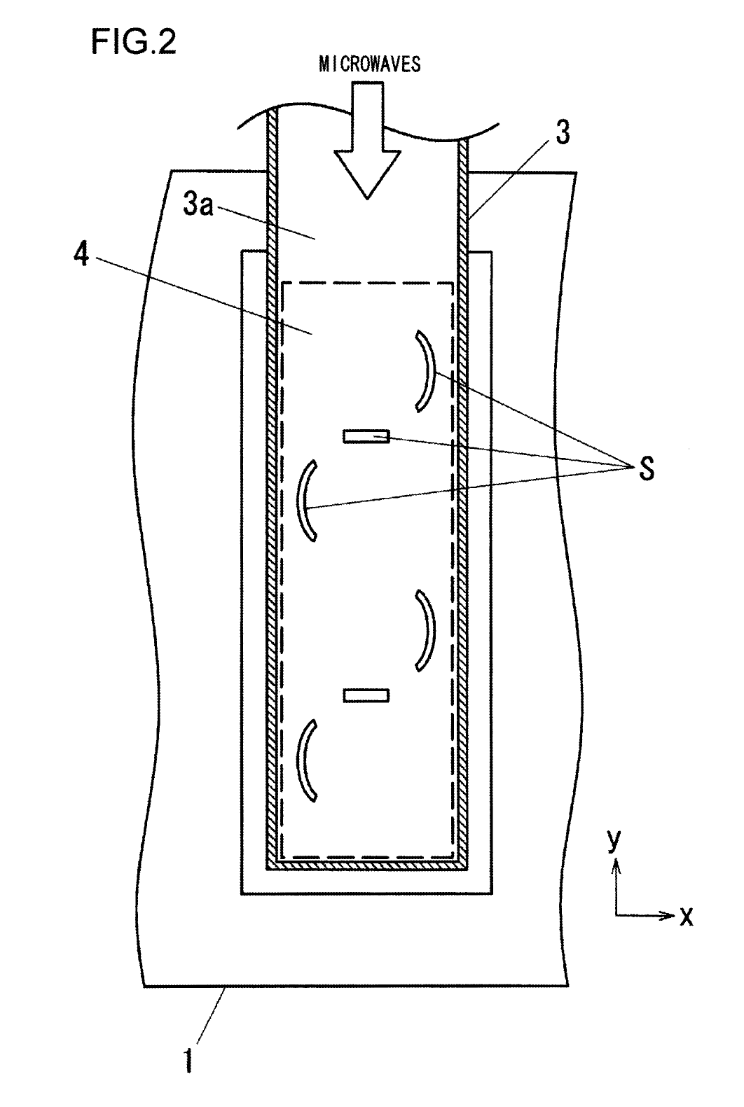

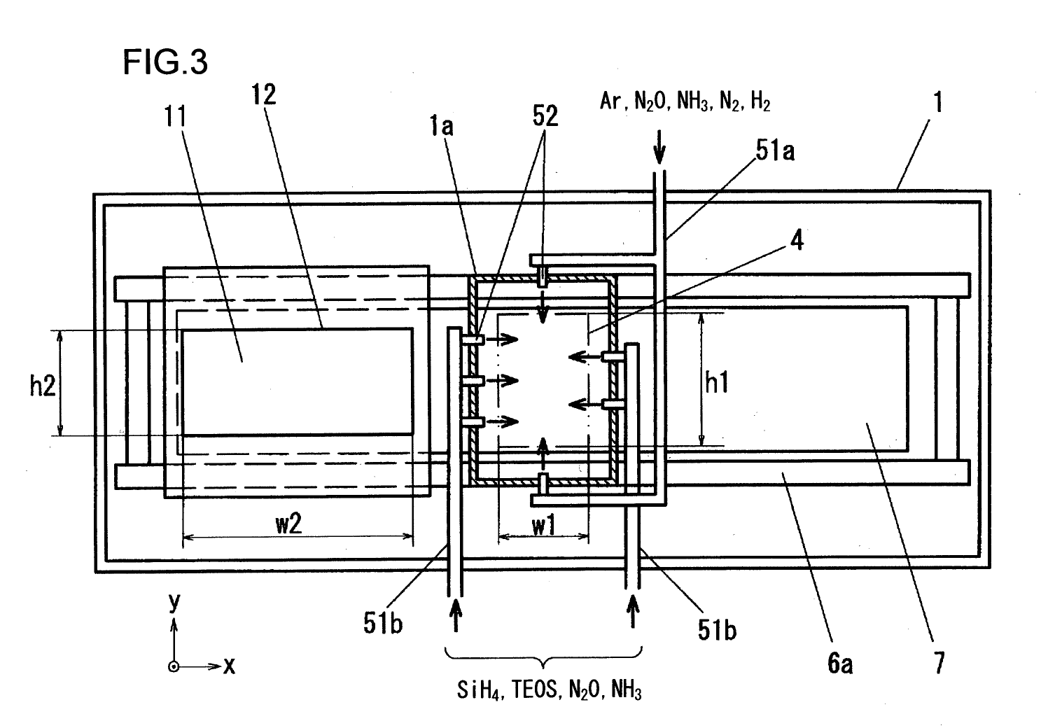

FIGS. 1 to 3 present diagrams explaining a first embodiment of the present invention and show a schematic configuration of a surface plasma CVD apparatus. FIG. 1 provides a cross-sectional view as seen from the front side and FIG. 2 provides a cross-sectional view along a line A-A in FIG. 1. FIG. 3 provides a cross-sectional view taken along a line B-B in FIG. 1. The CVD apparatus includes a vacuum chamber 1 in which a film forming process is performed, a microwave outputting unit 2 that supplies microwave when surface wave plasma is generated, a waveguide 3, a dielectric member 4, a gas feed device 5, a substrate moving device 6, and a control device 20.

On an upper part of the vacuum chamber 1 is provided a dielectric window 4 that has a plate-like form and is made of quartz, for example. A region designated by a symbol R that faces the dielectric window 4 is a film-forming processing region in which film forming on a substrate 11 is performed. On an upper part of the dielectric window 4 is mounted the waveguide 3, into which microwave (for example microwave with a frequency of 2.45 GHz) is input. The microwave outputting unit 2 includes a microwave power source, a microwave oscillator, an isolator, a directional coupler, and a matching box.

As indicated in broken line in FIG. 2, the dielectric window 4 has a rectangular shape which is oblong in the y-direction. As shown in FIG. 1, an upper surface of the dielectric window 4 contacts a bottom plate 3a of the waveguide 3. The portion of the bottom plate 3a that contacts the dielectric window 4 is formed of a plurality of slot antennae S, which are openings through which microwaves from the waveguide 3 are radiated. The microwaves introduced from the microwave outputting unit 2 form standing waves in the waveguide 3.

As shown in FIG. 3, gas for generating plasma and a material process gas for film formation that are to be fed from the gas feed device 5 are introduced into the vacuum chamber 1 through gas feed pipes 51a, 51b. In the vacuum chamber 1, a support member 1a of a rectangular shape is provided so as to surround the periphery of the dielectric window 4. The gas feed pipes 51a, 51b are fixed to the support member 1a. Plasma is formed in a region surrounded by the support member 1a. The gas from the gas feed device 5 is ejected to a plasma region in the support member 1a from the gas ejection part 52. The gas feed device 5 is provided with a mass flow controller for each gas species. By controlling each mass flow controller by means of a control device 20, on/off of the flow and control of flow rate for each gas can be performed.

The gas feed pipe 51a, which is provided at a position closer to the dielectric window 4 than the gas feed pipe 51b is, feeds a gas that is used as a material for a reactive species, such as N2, O2, N2O, NO, or NH3, and a rare gas such as Ar, He, or Ne. The gas feed pipe 51b feeds a material process gas such as TEOS, SiH4, N2O, NH3, N2, or H2. The gas feed pipes 51a, 51b are different in distance from the dielectric window 4; the gas feed pipe 51a is less distant from the dielectric window 4 than the gas feed pipe 51b. According to the present embodiment, the gas feed pipes 51a, 51b are arranged outside the support member 1a. The plasma is generated in the region surrounded by the support member 1a, so that the gas feed pipes 51a, 51b will not be exposed to the plasma. Accordingly, problems such as film formation on the gas feed pipes due to the arrangement of the gas feed pipes in the plasma region and occurrence of particles due to separation of the film thus formed on the gas feed pipes as conventionally encountered will not arise.

As shown in FIG. 1, the vacuum chamber 1 is evacuated by an evacuation device 9 connected thereto through a conductance valve 8. A turbo-molecular pump is used as the evacuation device 9. The substrate 11, which is a target on which a film is to be made, is mounted on a tray 12. The tray 12 on which the substrate is mounted is transported through a gate valve 10 onto a conveyer belt 6a in the substrate moving device 6 that is provided in the vacuum chamber 1. After completion of the film formation, the substrate 11 in a state where it is still mounted on the tray 11 is carried out from the vacuum chamber 1 through the gate valve 10. The substrate 11 may be directly mounted on the conveyer belt 6a without using the tray 12.

During the film formation, the substrate moving device 6 moves the tray 12 on the conveyer belt 6a to reciprocate in the horizontal direction (x-direction) in FIG. 1. As shown in FIG. 3, the dielectric window 4 has a rectangular shape whose shorter sides extend parallel to the direction of movement of the substrate 11. The longitudinal dimension (dimension along the y-direction) h1 of the dielectric window 4 is set to be larger than twice the longitudinal dimension h2 of the substrate 11. That is, they are set to be h1>h2. On the other hand, the lateral dimension w2 of the substrate 11 is unrelated to the width dimension w1 of the dielectric window 4 and w2 is proportional to a distance along which the substrate 11 moves.

A back plate 7 is provided in order to adjust the temperature of the substrate 11. Though not shown, a heater and a cooling pipe are provided so that the temperature can be controlled. For example, heating temperatures of the tray 12 and the substrate 11 are controlled to obtain desired CVD process conditions. By circulating a refrigerant through the cooling pipe, increases in temperatures of the substrate 11 and tray 12 due to plasma can be controlled. The back plate 7 is provided with a drive device 7a for driving the back plate 7 in the up and down direction (z-direction). By driving the drive device 7a, the gap between the back plate 7 and the tray 12 can be adjusted. The control device 20 controls operations of the plasma source 2, the gas feed device 5, the substrate moving device 6, the drive device 7a, the conductance valve 8, the evacuation device 9, and the gate valve 10.

(Explanation of operations) Next, taking the case in which a silicon nitride film is formed as an example, a film forming operation is explained. In this case, NH3 and N2 gas are fed from the gas feed pipe 51a and SiH4 gas is fed from the gas feed pipe 51b. When microwave radiated from the slot antenna S of the waveguide 3 is introduced into the vacuum chamber 1 through the dielectric window 4, gas molecules are ionized and dissociated by the microwave to generate plasma. If the electron density in the plasma near a microwave incident surface becomes higher than a cut-off density of the microwave, the microwave could not enter the plasma and propagate as a surface wave along an interface between the plasma and the dielectric window 4. As a result, surface wave plasma, to which energy is supplied via the surface wave, is formed near the dielectric window 4.

The surface wave plasma has a high plasma density near the dielectric window 4, which density decreases exponentially according as the surface wave plasma is parted from the dielectric window 4. In this manner, there are generated a high energy region and a low energy region depending on the distance of the surface wave plasma from the dielectric window 4. Accordingly, high-efficient radical generation and low damage high-rate film formation can be achieved by performing radical generation in the high energy region and introducing SiH4 as a material gas in the low energy region.

The substrate 11 is heated to a predetermined temperature in the previous step and transported onto the conveyer belt 6a in a state where it is mounted on the tray 12. Thereafter, the substrate moving device 6 starts reciprocatory driving of the tray 12. As a result of this reciprocatory motion, the substrate 11 reciprocates between a position on the left hand side of the plasma region (a first standby position shown in solid line in FIG. 1) and a position on the right hand side of the plasma region (a second standby position shown in broken line in FIG. 1). At either one of the left hand side and right hand side positions, the substrate 11 is in a state where it has fully passed over the opposite positions of the plasma region surrounded by the support member 1a.

While the substrate 11 is passing just under the region surrounded by the support member 1a where surface wave plasma is generated, a silicon nitride film layer is formed on the substrate 11. The thickness of the silicon nitride film layer formed on this occasion depends on the moving speed of the substrate 11. The moving speed is set to about 10 mm/sec to about 300 mm/sec, for example. The substrate moving device 6 performs deceleration operation after the substrate 11 has passed over the region under the support member 1a to stop the substrate, reverses the moving direction of the substrate 11, and completes acceleration of the substrate 11 to the above-mentioned moving speed before the substrate 11 enters the region under the support member 1a. That is, the support member 1a passes the region under the support member 1a at a constant moving speed. Therefore, a silicon nitride film layer having a uniform thickness depending on the moving speed is formed every time when the substrate 11 passes under the support member 1a. Ultimately, silicon nitride films having a layer number equal to total passage times in the reciprocatory motion are formed on the substrate 11.

For applications such as water vapor barrier or gas barrier, a thin film constituted by a plurality of layers of ultrathin film having different morphologies is demanded although they have the same film thickness, so that synthetic thin films formed by reciprocatory motion film formation become necessary. In the case of vacuum film forming processes such as sputtering and CVD, the state of the underlayer can be inherited when a thin film is formed. In the reciprocatory motion film formation as compared with the fixed stationary film formation, the inheritance of the state of the underlayer is alleviated. By positively changing ratios of introduced gases, for example, silane gas and ammonia gas, between to and fro motions, it becomes easy to control the film formation such that ultrathin films having different film qualities are stacked.

In the case of a capacity-coupled plasma CVD apparatus and an induction-coupled plasma CVD apparatus, stable electrical connection between cathode and anode is essential in order to obtain stable discharge. For this purpose, if the substrate on the anode side is moved during discharge, a balance in potential between the electrodes is changed so that stable discharge cannot be obtained, which causes a problem that uniformity in film quality, film thickness, and film formation speed cannot be obtained. It is known that moving a substrate induces abnormal discharge such as arching, which causes problems of deterioration of film quality and of extreme reduction in yield due to generation of particles. On the other hand, the surface wave plasma CVD method used in the present embodiment involves electrodeless discharge, so that even when the substrate is moved in such a manner that stable electric connection between the cathode and the anode is disturbed, there is no possibility that the above-mentioned problems will arise.

The surface wave plasma is plasma having a high density, and a low electron temperature and gives very little plasma damage to devices. Therefore, it enables formation of a protective film of an inorganic insulation thin film without giving damages even for those devices having low resistances to temperature and plasma, such as organic thin film devices.

### Second Embodiment

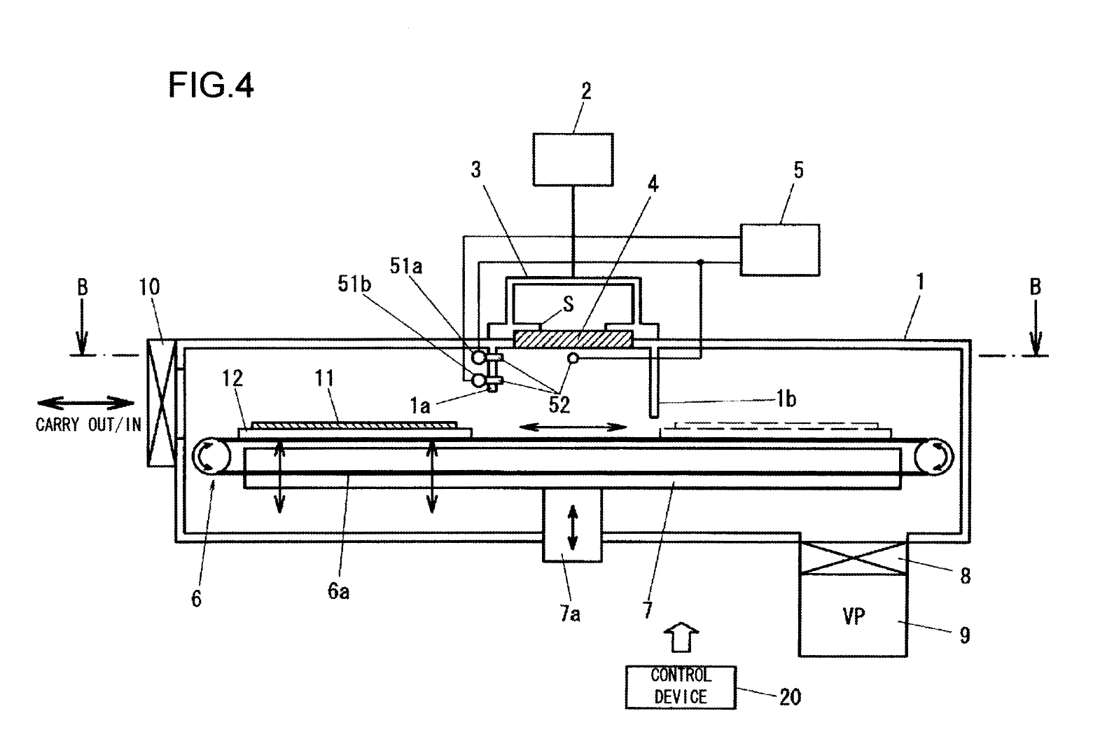

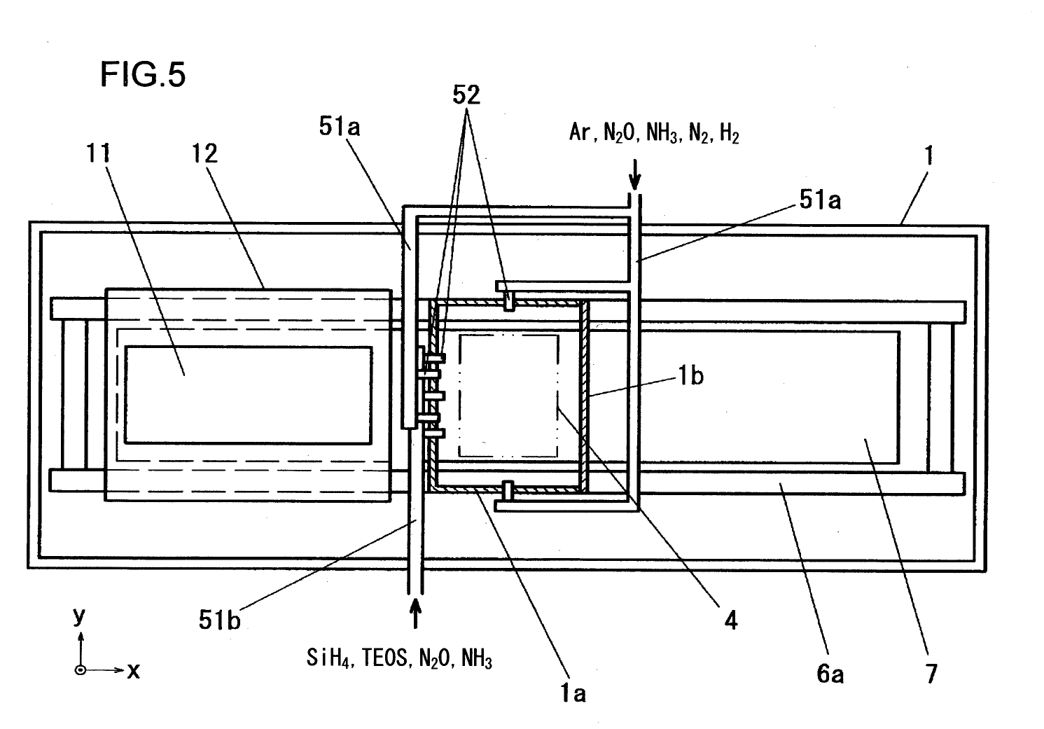

FIGS. 4, 5 present diagrams illustrating a second embodiment of the present invention. FIG. 4 presents a cross-sectional view as seen from the front and FIG. 5 presents a cross-sectional view taken along a line B=B in FIG. 4. As shown in FIGS. 4, 5, the second embodiment is different from the first embodiment in respect of the configuration of the gas feed pipes 51a, 51b and also in that a gas baffle plate 1b is provided in the second embodiment.

As shown in FIG. 5, a portion of the gas fed through the gas feed pipe 51a is ejected toward the gas baffle plate 1b and the other portion of the gas is ejected from both shorter sides of the rectangle so as to oppose each other. One or both of these portions are selectively used depending on the process conditions and the length of the longer side of the rectangle. The gas ejection parts 52 of the gas feed pipe 51a are provided at upper and lower sides of the support member 1a that constitutes three sides of the rectangle and at the longer side of the support member 1a on the left, respectively. On the other hand, the material process gas fed via the gas feed pipe 51b is ejected toward the gas baffle plate 1b through the gas ejection parts 52 provided at the left longer side of the support member 1a that constitutes the three sides of the rectangle. In the direction in which the material process gas is ejected, the gas baffle plate 1b is provided so as to oppose the flow of gas (see FIG. 4). As shown in FIG. 4, the lower end of the gas baffle plate 1b extends near the substrate 11.

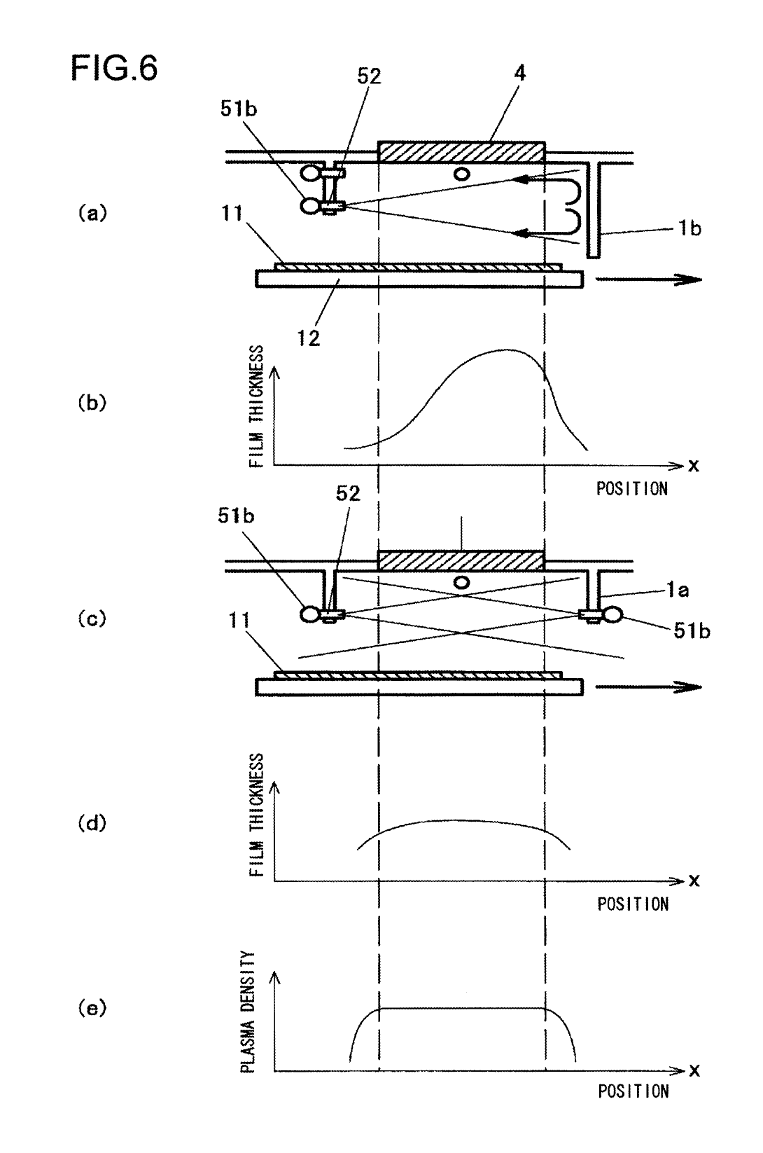

FIG. 6 presents a diagram explaining the function of the gas baffle plate 1b. Nozzles of the gas ejection part 52 provided on the gas feed pipe 51b is circular in cross-section and the material process gas ejected from the gas ejection part 52 in the direction toward the gas baffle plate 1b spreads conically. The ejected gas collides against the gas baffle plate 1b and then flows back as indicated by arrows to form a convection flow near the dielectric window 4. As a result, the distribution of film thickness when the substrate 11 remains still is such that the film thickness increases in a region on the right side of the dielectric window 4 as shown in FIG. 6(b). That is, the film thickness is increased since the material process gas can be efficiently used.

On the other hand, when no gas baffle plate 1b is provided and the material process gas is ejected from both the right and left sides, the distribution of film thickness is as shown in FIG. 6(d). FIG. 6(e) illustrates distribution of plasma density, and both the configurations shown in FIGS. 6(a), (c) provide distributions similar to each other.

In the configuration shown in FIG. 6(c), the distribution of gas is bilaterally symmetrical with respect to the center of the dielectric window 4, so that the distribution of film thickness is also bilaterally symmetrical. However, as compared with the configuration shown in FIG. 6(a), the configuration shown in FIG. 6(c) tends to provide a lower film formation rate due to escape of more material process gas outside from the region surrounded by the support member 1a of the rectangular shape, so that the thickness of the film formed is relatively small as compared with the case shown in FIG. 6(b).

On the other hand, in the case of the configuration shown in FIG. 6(a), the material process gas can be efficiently be used, so that the thickness of the film formed increases in the region on the right hand side of the dielectric window 4 as shown in FIG. 6(b). Further, the film formation is performed while the substrate 1 is being reciprocated in the x-direction to pass through the region under the support member 1a. So, even if there occur non-uniformities in distribution of film thickness as shown in FIG. 6(b), such non-uniformities are averaged and thin films having a uniform film thickness can be formed. Thus, according to the second embodiment, film formation speed can further be improved, while achieving uniformity of the resultant thin film.

### Third Embodiment

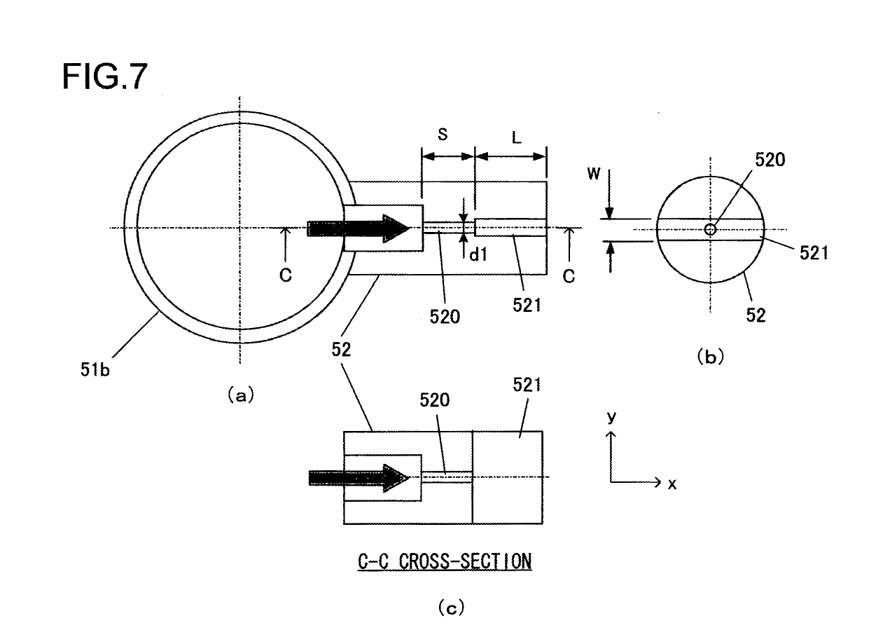

FIGS. 7-10 present diagrams illustrating a third embodiment of the present invention. For providing high density plasma such as surface wave plasma, how to introduce the material process gas is an essential factor for obtaining uniformity in film quality and film thickness. As mentioned above, the surface wave plasma has generated therein a higher energy region and a lower energy region depending on the distance from the dielectric window 4 and there is a suitable position at which the material process gas is to be introduced.

According to the first and second embodiments mentioned above, each nozzle of the gas ejection part 52 that ejects the material process gas therethrough has a circular shape and the gas is ejected conically as shown in FIG. 6(a). As a result, even when the gas is introduced at the best-suited position, a relatively large amount of the gas will turn away upwards or downwards. This influences on uniformities in film forming speed, film quality, film thickness, and so on. Accordingly, according to the present embodiment, the structure of the gas ejection part 52 is designed such that the distribution of the gas to be ejected can be improved.

FIG. 7(a) presents an enlarged diagram showing a portion of the gas ejection part 52. FIG. 7(b) presents a diagram showing the gas ejection part 52 as seen from the direction of ejection. FIG. 7(c) presents a cross-sectional view taken along a line C-C. The material process gas in the gas feed pipe 51b passes through holes 520 and then is ejected through a slit 521. The material process gas has an increased flow rate after it passes through the hole 520 having a diameter of dl and a length of S, and as a result, the impetus of ejection of the material process gas increases. The diameter dl and the length S of the hole 520 are set depending on the desired gas flow rate.

The gas ejected through the hole 520 tends to diffuse conically immediately after coming out of the gas hole 520. However, since the shape of the slit 521 through which the gas is ejected is designed to be a narrow gap space extending in the horizontal direction (direction parallel to the dielectric window 4), the gas is restricted with respect to motion in the up-and-down direction and thus is rectified to flow along the surface of the slit 521. Therefore, diffusion of the gas in the y-direction is wider than the case where no slit 521 is provided. The extent of diffusion in the y-direction can be adjusted by the length L of the slit 521.

The width W and the length L of the slit 521 are as follows. W is not smaller than 0.4 mm and not larger than 1.0 mm, with L=5W to 12W being preferred. By using the gas ejection part 52 having such a setup, the material process gas can be uniformly introduced into the space parallel to the dielectric window 4, thus improving the uniformity in film quality and film thickness.

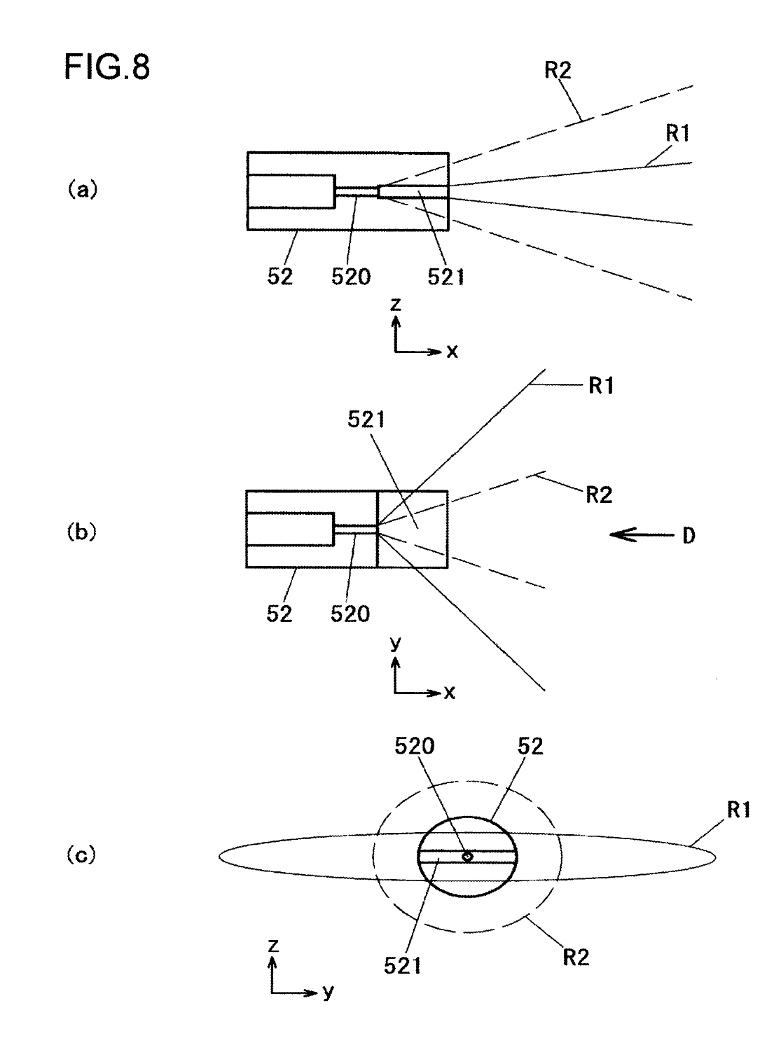

FIG. 8 schematically illustrates differences in the manner of diffusion of the ejected gas between the case with the slit 521 and the case without the slit 521, with (a) being a diagram as seen from the side, (b) being a diagram as seen from the top, and (c) being a diagram as seen from the direction D in (b). In any one of FIGS. 8(a) to 8(c), the solid line R1 indicates diffusion of the ejected gas according to the present embodiment and the broken line R2 indicates diffusion of the ejected gas in the case where no slit 521 is provided.

As mentioned above, the diffusion of the ejected gas in the vertical direction is confined by the slit 521 so that the width of the region indicated by the solid line R1 is narrowed as compared with the case without the slit 521 (broken line R2) as shown in FIG. 8(a). On the other hand, the diffusion of the ejected gas in the horizontal direction extends over a wider range in the case where the slit 521 is provided than the case where no slit 521 is provided to the extent that the distribution of gas is restricted in the vertical direction.

The diffusion of the gas as seen from the direction of the arrow D extends in both the y- and z-directions isotropically when no slit 521 is provided as shown in FIG. 8(c). When the slit 521 is provided as in the present embodiment, the distribution of the ejected gas extends widely in the y-direction (horizontal direction) but slightly in the z-direction (vertical direction). In other words, a flat-plate-like gas distribution is obtained.

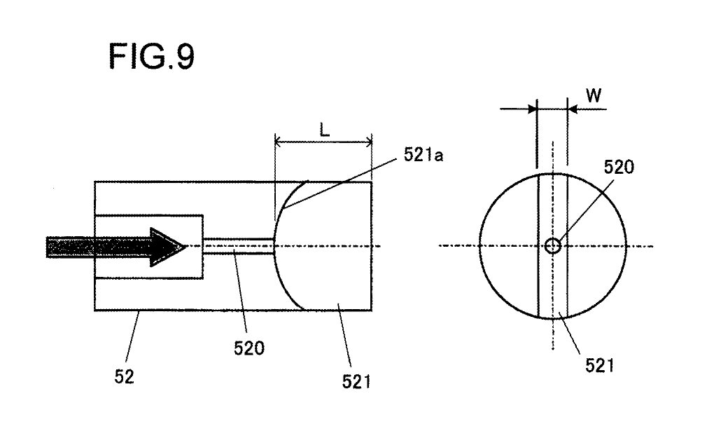

The shape of the gas ejection part 52 is not limited to one that is shown in FIG. 8 and it may be one that is shown in FIG. 9. In the example shown in FIG. 8, the slit 521 has a flat bottom surface. In contrast, the gas ejection part 52 shown in FIG. 9, the bottom surface 521a of the slit 521 is arc-like.

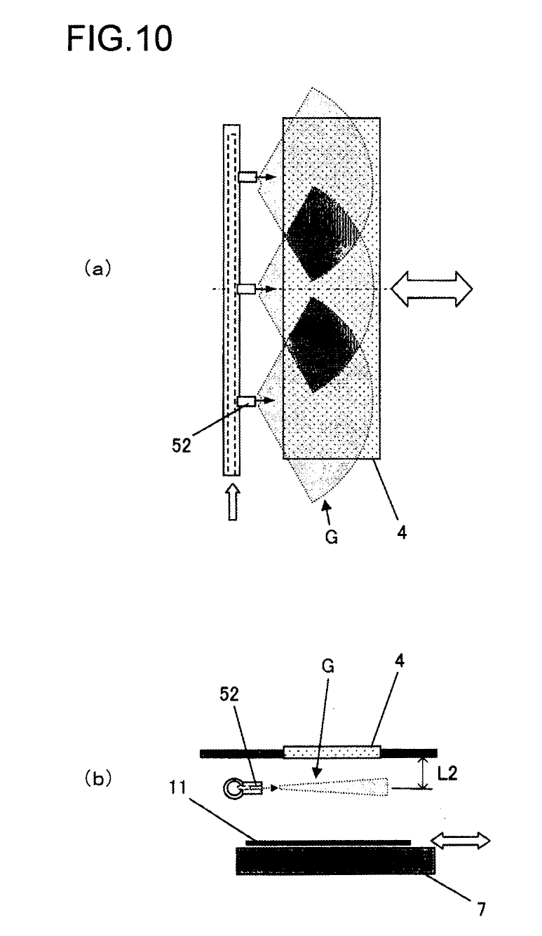

When the gas ejection part 52 that can form such a flat-plate-like gas distribution is used, the material process gas in the vacuum chamber 1 distributes as illustrated in FIG. 10. In FIG. 10, (a) is a plan view as seen from above the apparatus and (b) is a lateral view. As shown in FIG. 10(a), the distribution G of the material process gas ejected from each gas ejection part 52 is in the form of a fan that spreads in the horizontal direction. As a result, the material process gas can be introduced as concentrated at a desired height that is remote by a predetermined distance L2 from the dielectric window 4a and as spreading over the entire region opposing the dielectric window 4. With this configuration, uniform thin films can be efficiently formed.

Introduction of the material process gas at a predetermined optimal position by using the gas ejection part 52 as mentioned above can be applied to a conventional surface wave plasma CVD apparatus that performs film forming with holding the substrate in a still state. The method of introducing gas as used in the present embodiment is important not only for surface wave plasma CVD apparatus but also capacitive-coupled plasma (CCP) CVD apparatus, induction-coupled plasma (ICP) CVD apparatus and so on.

### Fourth Embodiment

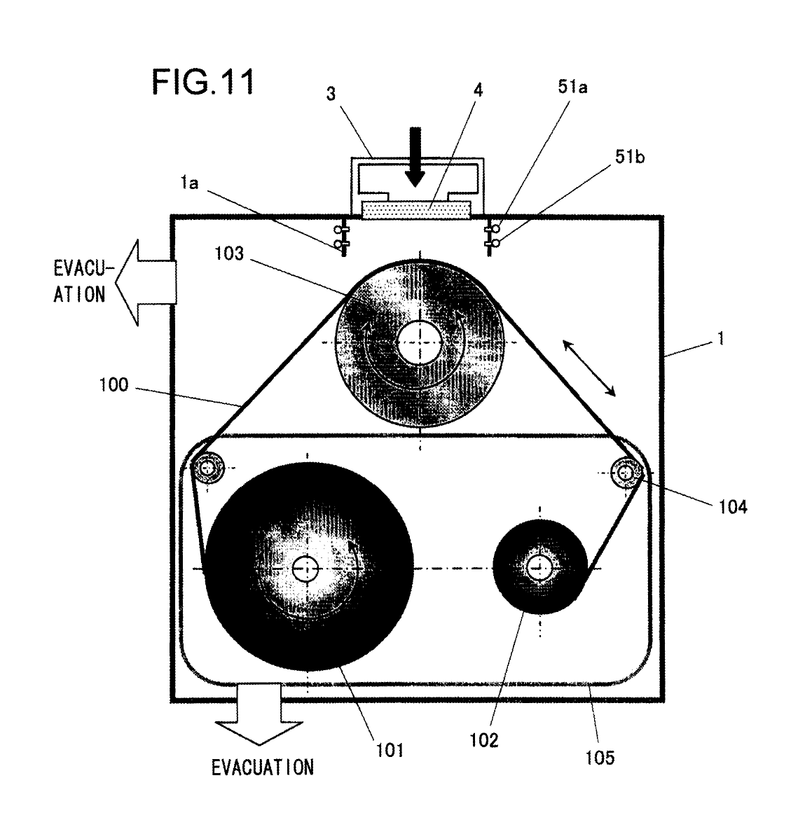

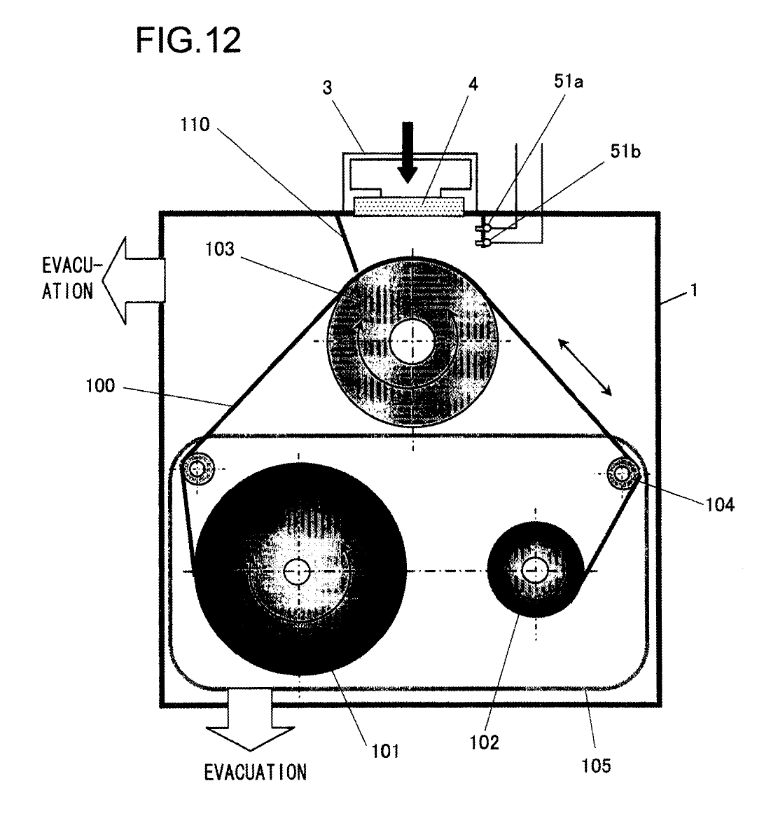

According to the first and second embodiments, the subject of film formation is a flat substrate such as a glass substrate. However, according to a fourth embodiment, a thin film is formed on a film-like substrate (hereafter, referred to as “film substrate”) as shown in FIGS. 11, 12. At an upper position of the vacuum chamber 1 are provided the dielectric window 4 and the waveguide 3. In the vacuum chamber 1, the rectangular support member 1a is provided so as to surround the dielectric window 4. Also, the gas feed pipes 51a, 51b are connected to the support member 1a.

A film substrate 100 is wound around a reel 101 as shown on the left hand side in the figure and the film substrate 100 on which a film has been formed is wound around a reel 102 as shown on the right hand side in the figure. The reels 101, 102 serve as a moving device that reciprocates over the film substrate 100. At a position facing the dielectric window 4 is provided a cylindrical back plate 103. The film substrate 100 between the reels 101, 102 is overlaid on the upper surface of the back plate 103. The back plate 103 is rotated in conjunction with the movement of the film substrate 100. Reference numeral 104 designates an idler that adjusts the tension of the film substrate 100.

The reels 101, 102 and the idler 104 are accommodated in a casing 105. The casing 105 is isolated from the vacuum chamber 1 except that it is provided with a slit serving as a gateway for the film substrate 100. The inner space of the casing 105 is evacuated separately from the vacuum chamber 1 and the pressure in the casing 105 is set to be somewhat lower than the pressure in the vacuum chamber 1. That is, by setting the casing 105 to be at a negative pressure with respect to the pressure of the vacuum chamber 1, contamination of the inside of the vacuum chamber 1 with atmosphere (gas and dust) in the casing 105 is prevented.

In the case of the apparatus shown in FIG. 11, a thin film may be formed on the surface of the substrate while running the film substrate 100 in one direction. Alternatively, a multilayer film may be formed by performing indexing and reciprocating a predetermined section of the film substrate to continue film formation. By reciprocation, similar effects to those obtained according to the first embodiment can be obtained.

FIG. 12 shows the case where a gas baffle plate 110 is provided in the apparatus shown in FIG. 11. The gas feed pipes 51a, 51b are arranged so as to face the gas baffle plate 110. Other configurations are similar to those of the apparatus shown in FIG. 11. With these configurations, similar advantageous effects to those obtained according to the second embodiment as mentioned above can be obtained. The configurations of the gas ejection part 52 explained with respect to the third embodiment may be adopted to the gas ejection part of the gas feed pipe 51a that feeds material process gas.

The surface wave plasma CVD apparatus that performs film formation by reciprocating the substrate 11 according to any one of the first to third embodiments can provide the following advantageous. (1) Since film formation is performed while reciprocating the substrate 11 such that it passes under the plasma region, that is, film formation processing region facing the dielectric window 4, the dimension W2 of the dielectric window 4 with respect to the direction of movement of the substrate can be made smaller than the dimension W1 of the substrate 11 in the direction of movement, so that cost can be decreased. In particular, by making the longitudinal direction of the substrate 11 coincident with the direction of movement, film formation can be performed on the substrate 11 having a greater dimension.

(2) Even when film formation speed becomes different depending on the position in the x-direction, non-uniformities in the film formation processing region can be averaged on the substrate 11 since the film formation is performed while moving the substrate 11 with respect to the dielectric window 4, so that thin films having a uniform thickness can be formed.

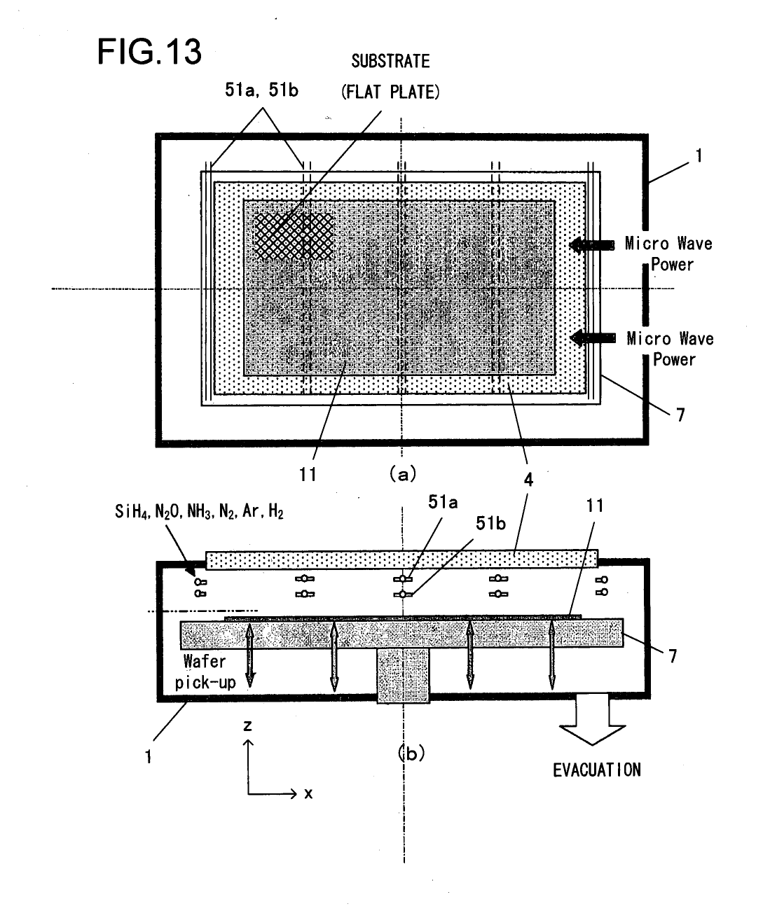

FIG. 13 shows, as a comparative example, an example of the conventional surface wave plasma CVD apparatus that does not perform reciprocation of the substrate. The substrate 11 is mounted on the back plate 7 and in this state film formation is performed. The density of plasma decreases near the periphery of the dielectric window 4, so that the dimension of the dielectric window 4 is set to be larger than that of the substrate 11. The number of waveguides to be installed is set depending on the area of the dielectric window 4. In FIG. 13, the waveguide is not shown and only the direction in which microwave is introduced is indicated by arrows. However, the apparatus is configured to have two waveguides. As mentioned above, the conventional apparatus that performs film formation with the substrate being fixed, the larger the area of the substrate, the larger the dielectric window 4 becomes accordingly, and the number of waveguides increases, so that the cost increases inevitably.

To perform uniform film formation over the entire substrate, the material gas must be uniformly fed within the entire plasma region. For the larger dielectric window 4, difficulty in introducing gas increases. It is undesirable that the gas feed pipes for introducing the gases are arranged in a space where plasma is being generated from the viewpoint of contamination. However, when the film formation region is broadened in the x-direction as shown in FIG. 13, the gas feed pipes must inevitably be arranged in the plasma in order to make uniform the distribution of the gas to be fed.

(3) On the other hand, in the apparatus according to any of the first to third embodiments, the dimension of the dielectric window 4 in the direction along which the substrate is being moved can be decreased to some extent as compared with the conventional apparatus, so that uniform gas can be fed without gas feed pipes being arranged in the plasma by arranging the gas feed pipes outside the support member 1a as shown in FIG. 3 and feeding the gas from the periphery of the support member 1a. As a result, there can be obtained an advantageous effect that the problem of contamination of plasma by arrangement of the gas feed pipes in the plasma can be avoided.

(4) In addition to the above-mentioned advantageous effects, another advantageous effect is obtained. That is, since the configuration of the apparatus is adopted such that film formation is performed while the substrate is being reciprocated over the film formation processing region facing the dielectric window 4, it facilitates formation of thin films having various film qualities differing in refractive index, internal stress and so on to change process conditions (gas flow rate ratio, pressure, etc.) for forward route along which the substrate 11 moves rightward in FIG. 1 and process conditions for backward route along which the substrate 11 moves leftward.

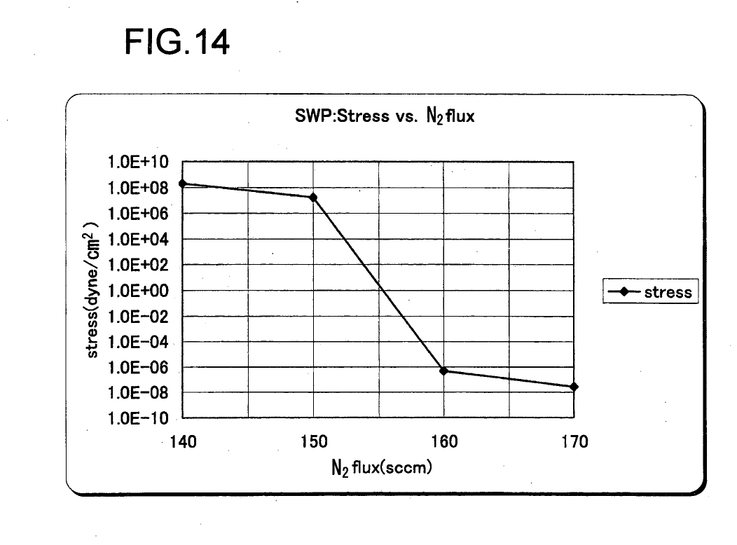

FIG. 14 presents a diagram illustrating the relationship between the flux ratio of nitrogen in the process gas and the internal stress of silicon nitride film, indicating a change in internal stress when the flux of nitrogen gas is changed while the flux of SiH4 is kept constant. When the flux of nitrogen is no higher than 150 sccm, the internal stress is positive, providing a tensile stress. On the contrary, if the flux of nitrogen is no lower than 160 sccm, the internal stress becomes negative, providing compression stress.

By using such properties and setting the flux of nitrogen to 160 sccm or higher in the film forming process on the forward route and forming a silicon nitride film layer (film thickness: about several nm) having an internal stress in the direction of compression while setting the flux of nitrogen to 150 sccm or lower in the film forming process in the backward route and forming a silicon nitride film layer (film thickness about several nm) having an internal stress in the direction of tension, a laminate thin film 100 having alternately laminated a silicon nitride film layer with compression stress and a silicon nitride film layer with tensile stress is formed. As a result, it becomes possible to form a thin film having a low internal stress.

Of course, it is possible for a conventional surface wave plasma CVD apparatus to form a multilayer film by forming a layer having tensile stress and a layer having a compression stress by independent processes. However, in the case of the surface plasma CVD apparatus according to the present embodiment, film formation is performed in such a manner that the substrate passes over positions facing the dielectric window 4, so that a very thin layer can be readily formed by increasing the moving speed of the substrate. As a result, by decreasing the film thickness for each layer to a considerable extent and continuously forming a plurality of layers, the stress of inversion of each layer at the interfaces thereof is kept low, so that stable thin films can be obtained.

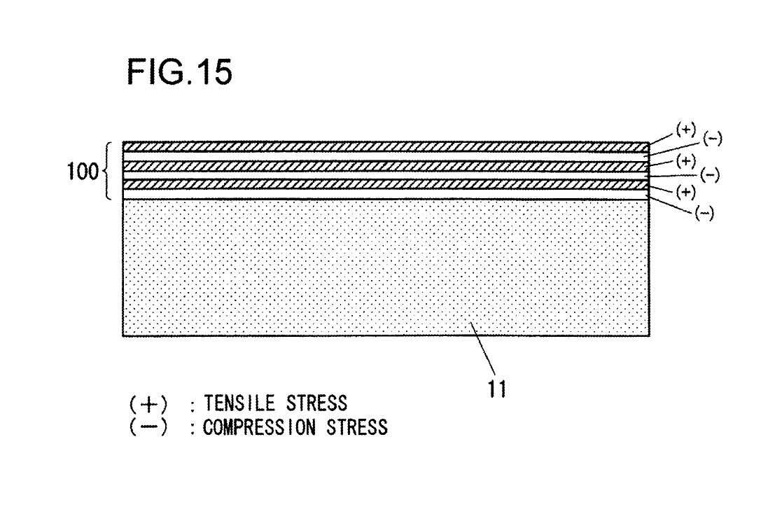

Such laminate films can be used as protective films for functional devices such as, for example, organic EL devices and devices for magnetic heads. In the case of organic EL devices, sometimes a silicon nitride film is formed thereon as a protective layer for protecting the organic EL layer from moisture and oxygen. Since the organic EL layer is not mechanically strong, the silicon nitride film thereon tends to separate therefrom if the internal stress of the silicon nitride film is high. By using, as such a protective layer, the laminate thin film 100 as shown in FIG. 15 having a very low internal stress, separation of the silicon nitride film can be prevented.

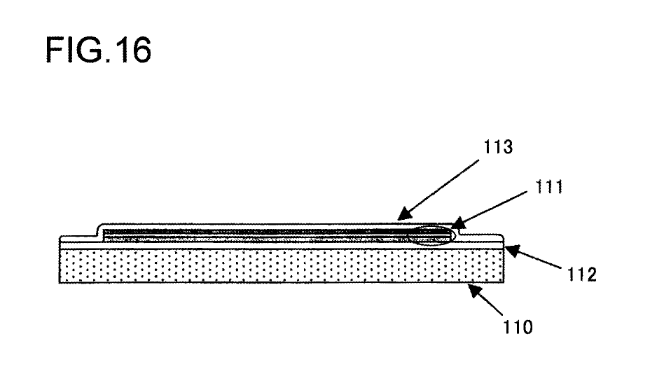

FIG. 16 shows an example of the configuration in which an organic EL device 111 is formed on the plastic film substrate 110. On the plastic film substrate 110 is formed an inorganic protective film 112, and on this inorganic protective film 112, the organic EL device 111 is formed. Further, an inorganic protective film 113 is formed so as to cover the organic EL device 111. The above-mentioned laminate thin film of silicon nitride is used for the inorganic protective films 112, 113.

The above-mentioned laminate thin film 100 provides a protective film having a low internal stress obtained by laminating films formed under different film formation conditions (nitrogen flux). Similarly, by adopting a multilayer structure constituted by alternately laminated films formed under slightly different film formation conditions, there can be formed a protective film having high protective function against permeation of moisture and oxygen as compared with a single-layer protective film having the same total film thickness.

In the above-mentioned example, a multilayer film formed by alternately laminating silicon nitrogen films having different nitrogen concentrations has been explained. However, the present invention may be applied to a multilayer film that is obtained by alternately laminating thin films having different compositions such as a multilayer film made of a silicon oxynitride film and a silicon nitride film. At timing when the silicon nitride film is to be formed, NH3, N2 gases are fed from the gas feed pipe 51a and SiH4 gas is fed from the gas feed pipe 51b in the same manner as mentioned above. On the other hand, at timing when a silicon oxynitride film is to be formed, SiH4 gas and N2O gas, or TEOS and oxygen gas are fed. And, each time when the substrate 11 passes through the region under the dielectric window 4, the gases to be fed are switched.

In the case of the surface wave plasma CVD apparatus shown in FIG. 1, only one substrate 11, which is relatively large, is mounted on the tray 12 when film formation is performed. However, film formation may be performed by mounting a plurality of small substrates on the tray 12. In this case, the region in which the plurality of relatively small substrates is mounted corresponds to the range of the subject of film formation.

Although carry in and carry out of the substrate 11 is performed through the gate valve 10 provided on the left side of the vacuum chamber 1, the gate valve 10 may be used for only carry in and a gate valve dedicated for carry out may be added on the right hand side (in the figure) of the vacuum chamber 1. By adopting such a configuration, a reduction in tact time can be achieved.

The above explanation is only exemplary and the present invention is not limited to the above-mentioned embodiments. The above-mentioned embodiments and variations may be combined in any combinations so far as the features of the present invention are not damaged.

1. A surface wave plasma CVD apparatus comprising:
a waveguide that is formed of a plurality of slot antennae and connected to a microwave source;
a dielectric member that introduces microwaves emitted from the plurality of slot antennae into a plasma processing chamber to generate surface wave plasma;
a moving device that reciprocates a subject of film formation in the form of a substrate such that the subject of film formation passes a film formation processing region facing the dielectric member;
a control device that controls reciprocation of the subject of film formation by the moving device depending on film formation conditions to perform film formation on the subject of film formation; and
a plurality of gas ejection parts provided in parallel in a direction at right angles to a direction along which the subject of film formation is moved at predetermined positions between the subject of film formation that passes through the film formation processing region and the dielectric member, wherein each of the plurality of gas ejection parts is provided with a slit extending parallel to the dielectric member, allowing the material process gas to be ejected through the slit in the direction along which the subject of film formation is moved.

2. A surface wave plasma apparatus according to claim 1, wherein
the plasma processing chamber is provided with a first standby region and a second standby region where the subject of film formation does not face the dielectric member such that the film formation processing region that faces the dielectric member is sandwiched by the first and second standby regions along a course of movement of the subject of film formation, and
the moving device reciprocates the subject of film formation between the first and second standby regions.

3. A surface wave plasma CVD apparatus according to claim 2, further comprising:
a gas baffle member that is arranged facing the direction of ejection of the gas ejection part and convects the ejected material process gas in a region where the surface wave plasma is generated.

4. A surface wave plasma CVD apparatus according to claim 1, wherein
a back plate that controls temperature of the subject of film formation is arranged over an entire region through which the subject of film formation is moved by the moving device.

5. A surface wave plasma CVD apparatus according to claim 4, further comprising:
a back plate driving device that varies a distance between the subject of film formation and the back plate.

6. A surface wave plasma CVD apparatus according to claim 5, wherein
the subject of film formation comprises a film-like substrate,
the back plate supports the film-like substrate in a region facing the dielectric member, and
the moving device reciprocates the film-like substrate so that a region of the film-like substrate in which a film is to be formed passes through the film formation processing region.

7. A surface wave plasma CVD apparatus according to claim 1, wherein
the subject of film formation comprises a functional device on a substrate, and
a protective film that protects the functional device is formed.

8. A method of forming a film on a subject of film formation by using a surface wave plasma CVD apparatus according to claim 1, the method comprising:
forming film layers under different film forming conditions between a forward route and a backward route of the reciprocatory motion, thereby forming a thin film having laminated the film layers formed under the different film forming conditions.

9. A surface wave plasma CVD apparatus according to claim 1, further comprising:
a gas baffle member that is arranged facing the direction of ejection of the gas ejection part and convects the ejected material process gas in a region where the surface wave plasma is generated.

10. A surface wave plasma CVD apparatus according to claim 9, wherein
a back plate that controls temperature of the subject of film formation is arranged over an entire region through which the subject of film formation is moved by the moving device.

11. A surface wave plasma CVD apparatus according to claim 10, further comprising:
a back plate driving device that varies a distance between the subject of film formation and the back plate.

12. A surface wave plasma CVD apparatus according to claim 11, wherein
the subject of film formation comprises a film-like substrate,
the back plate supports the film-like substrate in a region facing the dielectric member, and
the moving device reciprocates the film-like substrate so that a region of the film-like substrate in which a film is to be formed passes through the film formation processing region.

13. A surface wave plasma CVD apparatus according to claim 12, wherein
the subject of film formation comprises a functional device on a substrate, and
a protective film that protects the functional device is formed.

14. A surface wave plasma CVD apparatus according to claim 2, wherein
a back plate that controls temperature of the subject of film formation is arranged over an entire region through which the subject of film formation is moved by the moving device.

15. A surface wave plasma CVD apparatus according to claim 14, further comprising:
a back plate driving device that varies a distance between the subject of film formation and the back plate.

16. A surface wave plasma CVD apparatus according to claim 15, wherein
the subject of film formation comprises a film-like substrate,
the back plate supports the film-like substrate in a region facing the dielectric member, and
the moving device reciprocates the film-like substrate so that a region of the film-like substrate in which a film is to be formed passes through the film formation processing region.

17. A surface wave plasma CVD apparatus according to claim 16, wherein
the subject of film formation comprises a functional device on a substrate, and
a protective film that protects the functional device is formed.

18. A surface wave plasma CVD apparatus according to claim 1, wherein
a back plate that controls temperature of the subject of film formation is arranged over an entire region through which the subject of film formation is moved by the moving device.

19. A surface wave plasma CVD apparatus according to claim 18, further comprising:
a back plate driving device that varies a distance between the subject of film formation and the back plate.

20. A surface wave plasma CVD apparatus according to claim 19, wherein
the subject of film formation comprises a film-like substrate,
the back plate supports the film-like substrate in a region facing the dielectric member, and
the moving device reciprocates the film-like substrate so that a region of the film-like substrate in which a film is to be formed passes through the film formation processing region.

21. A surface wave plasma CVD apparatus according to claim 20, wherein
the subject of film formation comprises a functional device on a substrate, and
a protective film that protects the functional device is formed.
